(19) United States
(12) Patent Application Publication
(10) Pub. No.: US 2008/0054321 A1
(43) Pub. Date: Mar. 6, 2008

(54) CMOS image sensor and method for manufacturing the same

(75) Inventor: Hee Sung Shim, Gangneung-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/895,463

(22) Filed: Aug. 24, 2007

(30) Foreign Application Priority Data
Aug. 31, 2006 (KR) 10-2006-0083476

(51) Int. Cl. H01L 27/146; H01L 31/18

(52) U.S. Cl. 257/292; 438/59; 257/E31.083; 257/E27.133

(57) ABSTRACT

A CMOS image sensor for converting an optical signal into an electric signal includes a plurality of unit pixels, each having a photodiode on one side of an active region, a plurality of gate electrodes over the active region, and source/drain region on opposed sides of the gate electrodes, the source/drain region being formed by impurity implantation. The pixels include a transfer transistor, a reset transistor, a drive transistor, and a select transistor, and the gate electrode of the drive transistor extends from a region between the gate electrodes of the reset transistor and the select transistor to a region between the gate electrodes of the reset transistor and the transfer transistor.

### CROSS-REFERENCE TO RELATED APPLICATIONS

The present application claims priority under 35 U.S.C. 119 and 35 U.S.C. 365 to Korean Patent Application No. 10-2006-0083476 (filed on Aug. 31, 2006), which is hereby incorporated by reference in its entirety.

### BACKGROUND

The present disclosure relates to a complementary meal oxide semiconductor (CMOS) image sensor and a method for manufacturing the same, which can stably form a butting contact within a unit pixel.

Image sensors are semiconductor devices that convert optical signals into electric signals. Image sensors may be classified into charge coupled device (CCD) image sensors and CMOS image sensors.

Recently, a CMOS image sensor is considered as a next generation image sensor. The CMOS image sensor includes a plurality of MOS transistors formed on a semiconductor substrate using CMOS technology which employs a control circuit, a signal processing circuit and the like as a peripheral circuit. The MOS transistors are formed in a number proportional to the number of unit pixels. The CMOS image sensor adopts a switching scheme to sequentially detect outputs of the respective unit pixels through the MOS transistors.

FIG. 1 is a layout diagram illustrating a unit pixel of a related art 4T CMOS image sensor.

Referring to FIG. 1, a unit pixel of a 4T CMOS image sensor includes one photodiode 2 and first to fourth gate electrodes 11, 12, 13 and 14 of four transistors in an active region 1. The photodiode 2 is disposed in a wide portion of the active region 1, and the gate electrodes 11, 12, 13 and 14 are disposed over the remaining portion of the active region 1.

More specifically, a transfer transistor Tx, a reset transistor Rx, a drive transistor Dx, and a select transistor Sx are formed by the first gate electrode 11, the second gate electrode 12, the third gate electrode 13, and the fourth gate electrode 14, respectively. Source/drain regions of the respective transistors are formed in the active region 1 by implanting impurity ions into a region with the exception of the regions under the gate electrodes 11, 12, 13 and 14. A power supply voltage Vdd is applied to the source/drain region between the reset transistor Rx and the drive transistor Dx, and a ground voltage Vss is applied to the source/drain region on one side of the select transistor Sx.

However, there are limitations in manufacturing the CMOS image sensor as follows.

A metal line must also be connected between the reset transistor Rx (or the floating source/drain terminal between the transfer and reset transistors Tx and Rx) and the drive transistor Dx. Due to a relatively complicated interconnection of the metal line, a fill factor of the pixel may be reduced and a layout area per unit pixel may be increased so as to satisfy design rules for distances between metal lines.

Embodiments of the invention provide a CMOS image sensor, in which a drive transistor and an input of the drive transistor are connected through a contact between an active region and a polysilicon layer, thereby reducing a complexity of a metal line. Consequently, the fill factor of the unit pixel can be increased and the pixel size can be reduced. Embodiments of the invention also provide a method for manufacturing the CMOS image sensor.

In one embodiment, a CMOS image sensor (for converting an optical signal into an electric signal) includes a plurality of unit pixels, each having a photodiode on one side of an active region, a plurality of gate electrodes over the active region, and source/drain regions on opposite sides of the gate electrodes, the source/drain regions comprising ion implant regions, wherein the gate electrodes are part of a transfer transistor, a reset transistor, a drive transistor, and a select transistor, and the drive transistor gate electrode extends from a region between the reset transistor and the select transistor to a region between the reset transistor and the transfer transistor.

In another embodiment, a method for manufacturing a CMOS image sensor includes: forming a device isolation layer to define an active layer in a substrate; forming a polysilicon layer on the substrate; forming a spacer on a sidewall of the polysilicon layer; performing an ion implantation process on the resulting structure using the spacer as an ion implantation mask; removing the spacer; forming an oxide layer on the polysilicon layer; etching the oxide layer to form a contact hole; and depositing a metal in the contact hole to form a contact plug.

The details of one or more embodiments are set forth in the accompanying drawings and the description below. Other features will be apparent from the description and drawings, and from the claims.

### BRIEF DESCRIPTION OF THE DRAWINGS

FIG. 1 is a layout diagram illustrating a unit pixel of a related art CMOS image sensor.

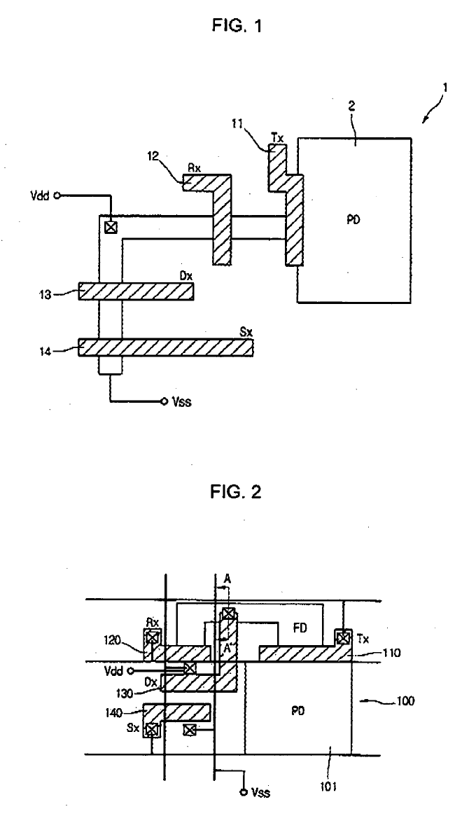

FIG. 2 is a layout diagram illustrating a unit pixel of a CMOS image sensor according to an embodiment.

FIGS. 3 through 6 are cross-sectional views illustrating a method for manufacturing a CMOS image sensor according to an embodiment of the invention.

### DETAILED DESCRIPTION OF THE EMBODIMENTS

Reference will now be made in detail to the embodiments of the present disclosure, examples of which are illustrated in the accompanying drawings.

In the drawings, the thicknesses of layers and regions are exaggerated for clarity. Like reference numerals are used to refer to like elements throughout the description of embodiments.

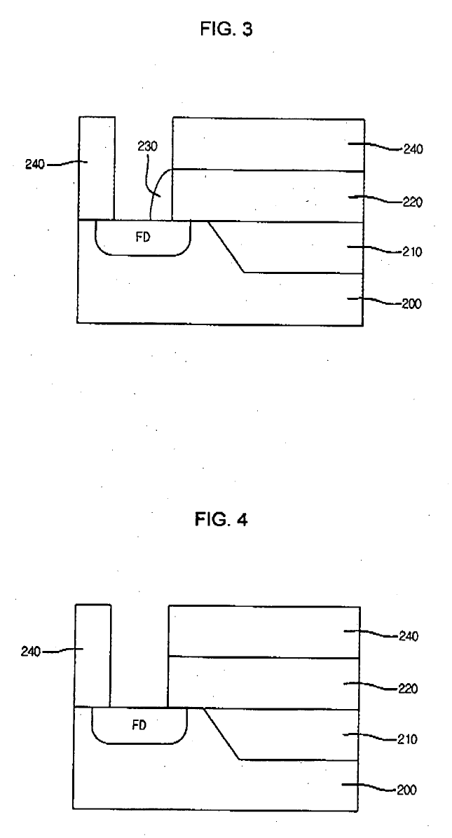

FIG. 2 is a layout diagram illustrating a unit pixel of a CMOS image sensor according to an embodiment. Referring to FIG. 2, a CMOS image sensor includes a photodiode 101 in a portion of an active region 100. Gate electrodes 110, 120, 130 and 140 of four transistors are disposed over the remaining portion of the active region 100.

More specifically, a transfer transistor Tx, a reset transistor Rx, a drive transistor Dx, and a select transistor Sx include the first gate electrode 11, the second gate electrode 12, the third gate electrode 13, and the fourth gate electrode 14, respectively. As shown in FIG. 2, the gate electrodes of the reset transistor, the transfer transistor, and the select transistor each have a long axis substantially aligned with and/or parallel to each other. That is, in a layout (top-down) view, the reset, transfer, and select transistor gates each have an axis along the longest dimension (e.g., the width) that is aligned with an axis along the longest dimension (e.g., the width) of another of the reset, transfer, and select transistor gates. In FIG. 2, the reset transistor gate 120 and the transfer transistor gate 110 are substantially aligned with each other. Similarly, the select transistor gate 140 is substantially parallel to the reset transistor gate 120 and the transfer transistor gate 110. Referring back to FIG. 2, in the active region 100 of the respective transistors, P-type impurity regions are under the first to fourth gate electrodes 110, 120, 130 and 140 (e.g., either by implantation prior to gate electrode formation, or by doping of the single crystal silicon substrate during its formation from a melt). Source/drain regions are formed in the active region 100 on opposite sides of the P-type impurity regions by implanting impurity ions.

During typical operation, a power supply voltage Vdd is applied between the drive transistor Dx the reset transistor Rx, and a ground voltage Vss is applied to the source/drain region on one side of the select transistor Sx. The transfer transistor Tx typically transfers photoelectric charges from the photodiode 101 to a floating diffusion layer (e.g., between the transfer transistor Tx and the reset transistor Rx). The reset transistor Rx may adjust and/or reset a voltage level of the floating diffusion layer. The drive transistor Dx typically acts or functions as a source follower, and may in one embodiment receive a gate voltage from the floating source/drain terminal between the transfer and reset transistors Tx and Rx which may ultimately determine the strength of the output signal from the pixel. The select transistor Sx may perform a switching operation to output pixel data (e.g., during a read operation by applying an active [low] read signal to the select gate 140).

Specifically, the gate electrode 130 (e.g., comprising polysilicon) of the drive transistor Dx may extend to a region between the transfer transistor Tx and the reset transistor Rx. As shown in FIG. 2, the drive transistor gate 130 has a first portion (e.g., between the reset transistor gate 120 and the select transistor gate 140) and an orthogonal second portion (e.g., along the axis A-A′), the first portion having long axis substantially aligned with and/or parallel to the reset, transfer, and select transistor gate electrodes, and the second portion having a long axis substantially perpendicular thereto. The second portion may be adjacent to and/or in contact with a butting contact (e.g., 270 in FIG. 6). Hence, a metal line in a unit pixel structure can be reduced.

In addition, oxide spacers are not on a sidewall of the drive gate polysilicon (e.g., an “end” sidewall, along the length of the drive gate 130 bisecting axis A-A′) in order for a stable contact (e.g., a butting contact 270 as shown in FIG. 6) between the active region 100 and the polysilicon layer 130 of the drive transistor.

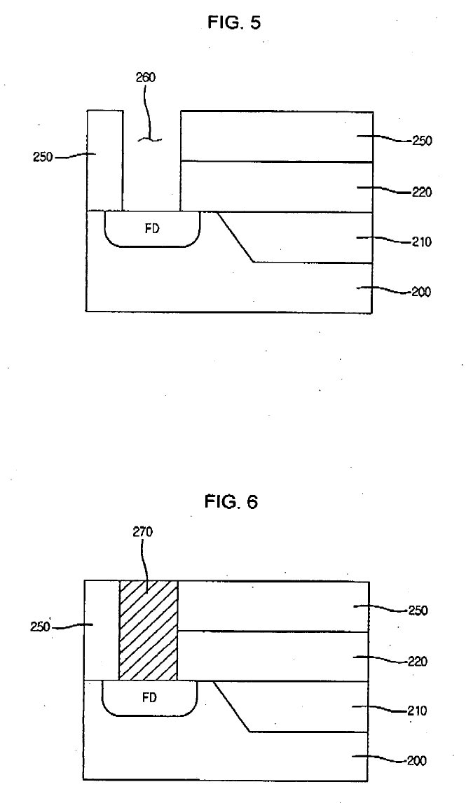

A method for manufacturing the CMOS image sensor will be described below with reference to FIGS. 3 through 6, which are cross-sectional views along line A-A′ of FIG. 2 illustrating a method for manufacturing the CMOS image sensor according to various embodiments of the invention.

Referring to FIG. 3, a shallow trench isolation (STI) layer 210 is formed as a device isolation layer to define an active region in a substrate 200. A gate oxide layer (not shown) and a polysilicon layer are deposited on the substrate 200 and patterned by photolithography to form gate electrodes (e.g., 110, 120, 130 and 140 in FIG. 2), of which an end portion 220 of the drive gate is shown in FIG. 3.

A spacer 230 is formed on a sidewall of the patterned polysilicon layer 220. The spacer 230 can be used as an ion implantation mask in a subsequent ion implantation process. Since the spacer 230 and the polysilicon layer 220 can be formed using a typical manufacturing process, their detailed description will be omitted. Thereafter, the source/drain regions are formed by photolithographic (resist) masking and ion implantation.

The source/drain implant resist mask is removed, and another photoresist layer 240 is coated on the polysilicon layer 220 and the substrate 200 so as to etch and remove the spacer 230 from the end of the drive transistor gate. The reason why a photolithography process is performed using the photoresist layer 240 is that a contact stability to the active region (and in one embodiment, the floating source/drain region between the transfer and reset transistors Tx and Rx) is improved by extending the polysilicon layer of the drive transistor Dx (e.g., forming a second, substantially orthogonal portion from the substantially parallel portion between the reset and select transistors Rx and Sx to the floating source/drain region, instead of routing a metal line in a layer of metal above essentially the same area of the pixel). That is, a spacer is formed on a sidewall of the gate electrode of the drive transistor Dx when a process of forming the gate electrode is performed. A process of removing the spacer from the end of the drive transistor gate electrode is further performed.

If the spacer 230 is not removed, a contact area of a contact plug, which will be described later, is reduced by an area of the spacer 230. This may lead to a poor interlayer connection. In order to prevent the poor interlayer connection caused by the area of the spacer 230, a process of removing the spacer 230 is performed before forming a contact hole for a contact plug. However, when the spacer 230 includes or consists essentially of a material that can be etched at substantially the same rate as the dielectric in which the contact hole is formed (e.g., silicon dioxide, undoped or doped with fluorine or boron and/or phosphorous), then the spacer 230 does not need to be removed from the end of the drive transistor gate 220 at this time (although such an embodiment may not be suitable for a process that includes contacts that are self-aligned to corresponding source/drain regions). However, when the spacer 230 includes or consists essentially of a material that is generally not etched (e.g., silicon nitride) when etching the dielectric in which the contact hole is formed (e.g., silicon dioxide, undoped or doped with fluorine or boron and/or phosphorous), then the spacer 230 should be removed from the end of the drive transistor gate 220 at this time.

Referring to FIG. 4, a selective etching process may be performed to remove the spacer 230 from the sidewall of the polysilicon layer 220 using the photoresist layer 240 as an etch mask.

Referring to FIG. 5, after removing the spacer 230, the coated photoresist layer 240 is removed and a dielectric (e.g., oxide) layer 250 is deposited on the substrate 200. The dielectric layer 250 is then etched to form a contact hole 260. As mentioned above, the spacer-removing photolithography step can be avoided when the spacer is made of a material that can be etched at a similar rate to the dielectric layer 250. In another embodiment, when spacer 230 comprises or consists essentially of silicon nitride, it can be removed at the time of etching the dielectric layer 250 when the dielectric layer 250 includes a bottom silicon nitride (e.g., etch stop) layer.

Referring to FIG. 6, a metal is deposited in the contact hole 260 to form a contact plug 270 serving to electrically connect and/or transfer a signal between an upper layer (e.g., drive transistor gate 220) and a lower layer (e.g., the floating source/drain region between the transfer and reset transistors). By extending the polysilicon layer of the drive transistor Dx to the region between the reset transistor Rx and the transfer transistor Tx, it is unnecessary to form a separate metal line to make such an electrical connection. The process of removing the spacer from the sidewall of the polysilicon layer 220 is performed so as to improve the contact efficiency between the active region (e.g., the floating source/drain region and the drive transistor gate electrode when the corresponding polysilicon layer extends thereto.

According to the embodiments of the CMOS image sensor and the method for manufacturing the same, it is unnecessary to form a separate metal line between the drive transistor and the reset transistor or the floating source/drain region adjacent thereto. The stability of the process of forming the butting contact can be obtained by selectively removing only the spacer formed in the butting contact region within the unit pixel.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A CMOS image sensor, comprising a plurality of unit pixels each including:
a photodiode on one side of an active region;
a transfer transistor, a reset transistor, a drive transistor, and a select transistor in the active region, wherein a gate electrode of the drive transistor extends from a region between a gate electrode of the reset transistor and a gate electrode of the select transistor to a region between the gate electrode of the reset transistor and a gate electrode of the transfer transistor.

2. The CMOS image sensor according to claim 1, wherein the transfer transistor transfers photoelectric charges from the photodiode to a floating diffusion layer, the drive transistor resets a voltage level of the floating diffusion layer, the drive transistor acts as a source follower, and the select transistor performs a switching operation to output pixel data.

3. The CMOS image sensor according to claim 1, wherein the reset transistor, drive transistor, and select transistor further comprise source/drain regions on opposed sides of the corresponding gates.

4. The CMOS image sensor according to claim 3, wherein the source/drain regions comprise a plurality of ion impurity implant regions.

5. The CMOS image sensor according to claim 1, wherein the transfer transistor is configured to transfer photoelectric charges from the photodiode to a floating diffusion layer between the transfer transistor and the reset transistor.

6. The CMOS image sensor according to claim 5, wherein the drive transistor gate electrode is configured to receive a voltage level of the floating diffusion layer.

7. The CMOS image sensor according to claim 6, further comprising a metal contact along a sidewall of the drive transistor gate electrode, in further contact with the floating diffusion layer.

8. The CMOS image sensor according to claim 1, wherein the select transistor is configured to output pixel data during a switching operation thereof.

9. The CMOS image sensor according to claim 1, wherein the gate electrodes of the reset transistor, the transfer transistor, and the select transistor each have a long axis substantially aligned with and/or parallel to each other.

10. The CMOS image sensor according to claim 9, wherein the gate electrode of the drive transistor has a first portion and an orthogonal second portion, the a first portion having long axis substantially aligned with and/or parallel to the gate electrodes of the reset transistor, transfer transistor, and select transistor, and the second portion having a long axis.

11. The CMOS image sensor according to claim 10, wherein the first portion of the drive transistor gate electrode is between the reset transistor gate electrode and the select transistor gate electrode.

12. A method for manufacturing a CMOS image sensor, comprising:
forming a device isolation layer to define an active region in a substrate;
forming a polysilicon layer on the substrate;
forming a spacer on a sidewall of the polysilicon layer;
performing an ion implantation process on the resulting structure using the spacer as an ion implantation mask;
removing the spacer;
forming an oxide layer on the polysilicon layer;
etching the oxide layer to form a contact hole; and
depositing a metal in the contact hole to form a contact plug.

13. The method according to claim 12, further comprising forming a gate electrode from the polysilicon layer.

14. The method according to claim 13, wherein the gate electrode is a reset transistor gate electrode.

15. The method according to claim 12, further comprising forming a plurality of gate electrodes from the polysilicon layer.

16. The method according to claim 15, wherein the gate electrodes comprise a reset transistor gate electrode, a transfer transistor gate electrode, a drive transistor gate electrode, and a select transistor gate electrode.

17. The method according to claim 16, wherein the drive transistor gate electrode extends from a region between the reset transistor gate electrode and the select transistor gate electrode to a region between the reset transistor gate electrode and the transfer transistor gate electrode.

18. The method according to claim 12, wherein removing the spacer comprises:
coating a photoresist layer on the polysilicon layer; and
selectively etching the [?] using the photoresist layer as an etch mask.

19. The method according to claim 12, wherein forming the oxide layer comprises depositing the oxide layer on the polysilicon layer.

20. A method for manufacturing a CMOS image sensor, comprising:
forming a device isolation layer in a substrate;
forming a plurality of gate electrodes on the substrate;
forming a spacer on sidewalls of the gate electrodes;
performing an ion implantation process on the resulting structure using the spacer as an ion implantation mask;
forming a dielectric layer on the polysilicon layer;
etching the dielectric layer and any underlying, exposed spacer area to form contact holes; and
depositing a metal in the contact hole to form a contact plug.
